(19) United States
(12) Patent Application Publication
(10) Pub. No.: US 2026/0157225 A1
(43) Pub. Date: Jun. 4, 2026

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Ki Yeul Yang, Seoul (KR); Eun Bin Choi, Gyeonggi-do (KR)

(73) Assignee: Amkor Technology Singapore Holding Pte. Ltd., Singapore (SG)

(21) Appl. No.: 18/967,371

(22) Filed: Dec. 3, 2024

(51) Int. Cl. H01L 23/00; H01L 23/31; H01L 25/00; H01L 25/03

(52) U.S. Cl. CPC H10W 74/141; H10W 90/00; H10W 72/222; H10W 72/324; H10W 74/15; H10W 90/724; H10W 90/732

(57) ABSTRACT

In one example, an electronic device comprises a substrate comprising a first side, a second side opposite to the first side, a dielectric structure, and a conductive structure, a first electronic component over the first side of the substrate and coupled to the conductive structure, an encapsulant over the first side of the substrate and covering a lateral side of the first electronic component, wherein the encapsulant has a first side facing away from the substrate, and a cavity in the first side of the encapsulant, a second electronic component over the first electronic component and over the encapsulant, a vertical interconnect in the encapsulant and coupled to the conductive structure, and a connector coupled to the vertical interconnect and the second electronic component, wherein the connector is in the cavity. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2H show cross-sectional views of an example method for manufacturing an example electronic device.

FIG. 3 shows a cross-sectional view of an example electronic device.

FIGS. 4A to 4D show cross-sectional views of an example method for manufacturing an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features. The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to a mechanical or electrical coupling.

### DESCRIPTION

In one example, an electronic device comprises a substrate comprising a first side, a second side opposite to the first side, a dielectric structure, and a conductive structure, a first electronic component over the first side of the substrate and coupled to the conductive structure, an encapsulant over the first side of the substrate and covering a lateral side of the first electronic component, wherein the encapsulant has a first side facing away from the substrate, and a cavity in the first side of the encapsulant, a second electronic component over the first electronic component and over the encapsulant, a vertical interconnect in the encapsulant and coupled to the conductive structure, and a connector coupled to the vertical interconnect and the second electronic component. In some examples, the connector is in the cavity.

In another example, an electronic device comprises a substrate having a first side, a second side opposite to the first side, a dielectric structure, and a conductive structure, a first electronic component coupled to the first side of the substrate and coupled to the conductive structure, wherein the first electronic component has an active side facing the first side of the substrate, and a backside facing away from the first side of the substrate, an encapsulant coupled to the first side of the substrate and over a lateral side of the substrate, wherein the encapsulant comprises a central portion, and a step located between the central portion and a lateral side of the encapsulant, wherein the step comprises a vertical portion of the encapsulant and a lower horizontal portion of the encapsulant, a connector over the lower horizontal portion of the encapsulant and coupled to the conductive structure, and a second electronic component is coupled to the connector and having a first side facing the encapsulant and a second side facing away from the encapsulant. In some examples, the central portion of the encapsulant comprises an upper horizontal portion, and the lower horizontal portion of the step is lower than the upper horizontal portion.

In yet another example, a method to manufacture an electronic device comprises providing a substrate comprising a first side, a second side opposite to the first side, a dielectric structure, and a conductive structure, providing a vertical interconnect over the first side of the substrate and coupled to the conductive structure, providing a first electronic component over the first side of the substrate and coupled to the conductive structure, providing an encapsulant over the first side of the substrate and covering a lateral side of the first electronic component and a lateral side of the vertical interconnect, wherein the encapsulant has a first side facing away from the substrate, providing a cavity in the first side of the encapsulant at a lateral side of the encapsulant, providing a connector coupled to the vertical interconnect, wherein the connector is in the cavity, an providing a second electronic component over the first electronic component and over the encapsulant, wherein the second electronic component is coupled to the connector.

Other examples are included in the present disclosure. Such examples may be found in the figures, in the claims, or in the description of the present disclosure.

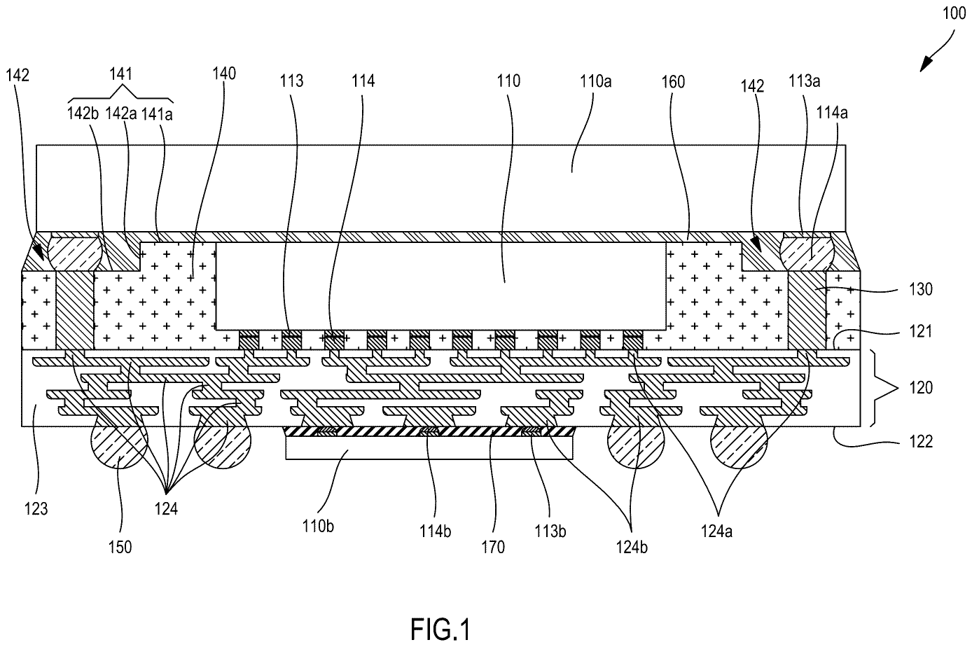

FIG. 1 shows a cross-sectional view of an example electronic device 100. In the example shown in FIG. 1, electronic device 100 can comprise electronic component 110, electronic component 110a, electronic component 110b, substrate 120, vertical interconnects 130, encapsulant 140, external interconnects 150, underfill material 160, and underfill material 170.

Substrate 120 can comprise first side 121 and second side 122 opposite first side 121. Substrate 120 can comprise dielectric structure 123 and conductive structure 124. Conductive structure 124 can comprise inward terminals 124a located on first side 121 of substrate 120 and outward terminals 124b located on second side 122 of substrate 120. Encapsulant 140 can comprise first (or upper) side 141. First side 141 is oriented away from substrate 120. First side 141 can include and define a cavity 142. For example, cavity 142 can be provided in an upper horizontal portion 141a of first side 141. In some examples, cavity 142 can be defined by vertical portion 142a and lower horizontal portion 142b of first side 141. Lower horizontal portion 142b can be lower (e.g., residing on a different horizontal plane) than upper horizontal portion 141a of encapsulant 140. In such examples, the thickness of encapsulant 140 at the upper horizontal portion 141a can be greater than the thickness of encapsulant 140 at lower horizontal portion 142b. Vertical portion 142a can extend between lower horizontal portion 142b and upper horizontal portion 141a. In some examples, vertical portion 142a can be generally orthogonal to lower horizontal portion 142b. In some examples, upper horizontal portion 141a can be located at a central portion of encapsulant 140 (e.g., over electronic component 110), and cavity 140 can be located at a lateral side, lateral portion, or perimeter of encapsulant 140.

Electronic component 110 can include contacts 113. Connectors 114 can couple contacts 113 of electronic component 110 to inward terminals 124a of substrate 120. Contacts 113a of electronic component 110a can be coupled to vertical interconnects 130 via connectors 114a. Contacts 113b of electronic component 110b can be coupled to outward terminals 124b of substrate 120 via connectors 114b. In some examples, electronic component 110 can be referred to as a first electronic component, electronic component 110a can be referred to as a second electronic component, and electronic component 110b can be referred to as a third electronic component, although the scope of the disclosed subject matter is not limited in this respect.

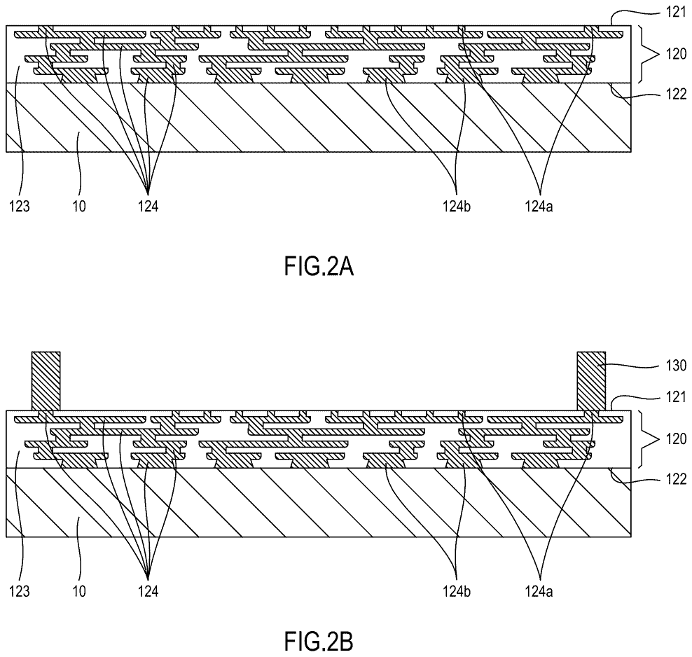

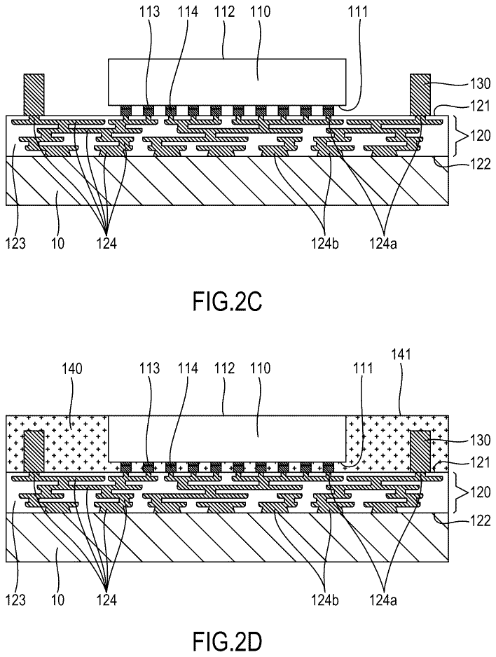

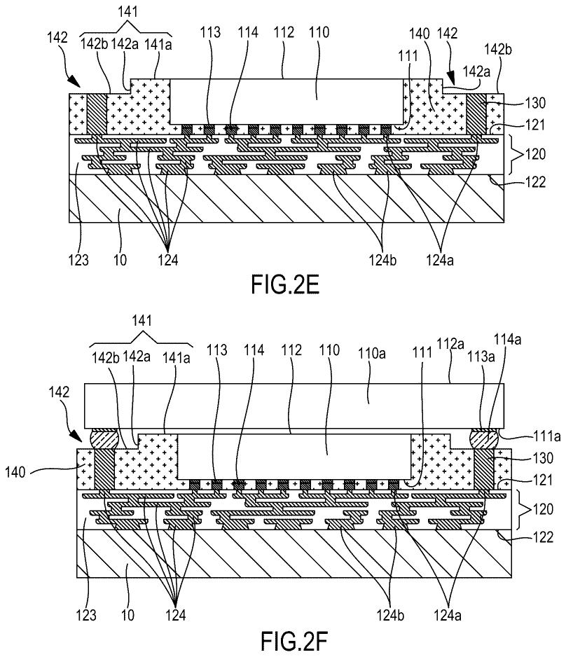

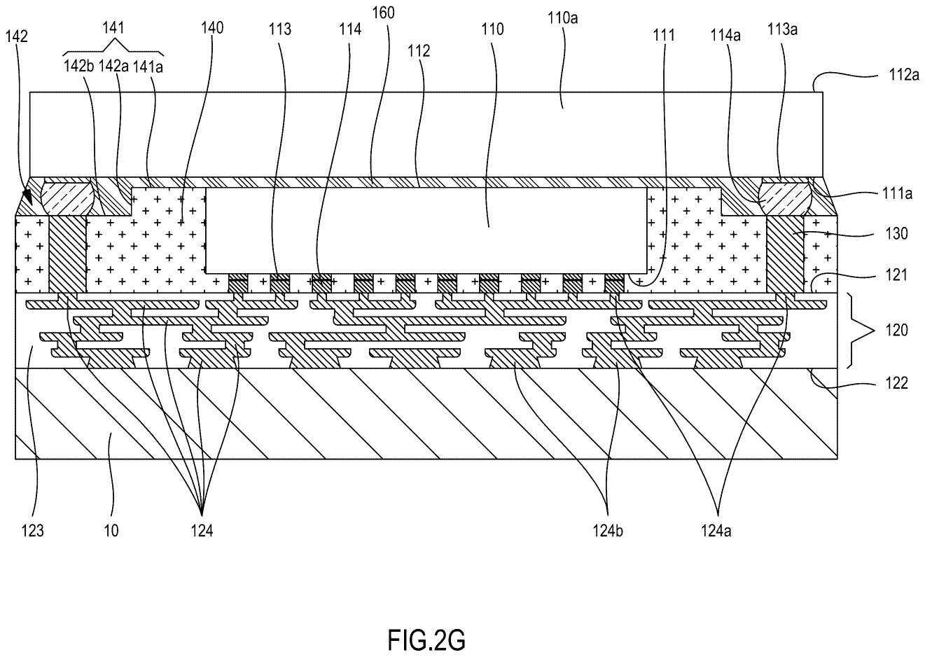

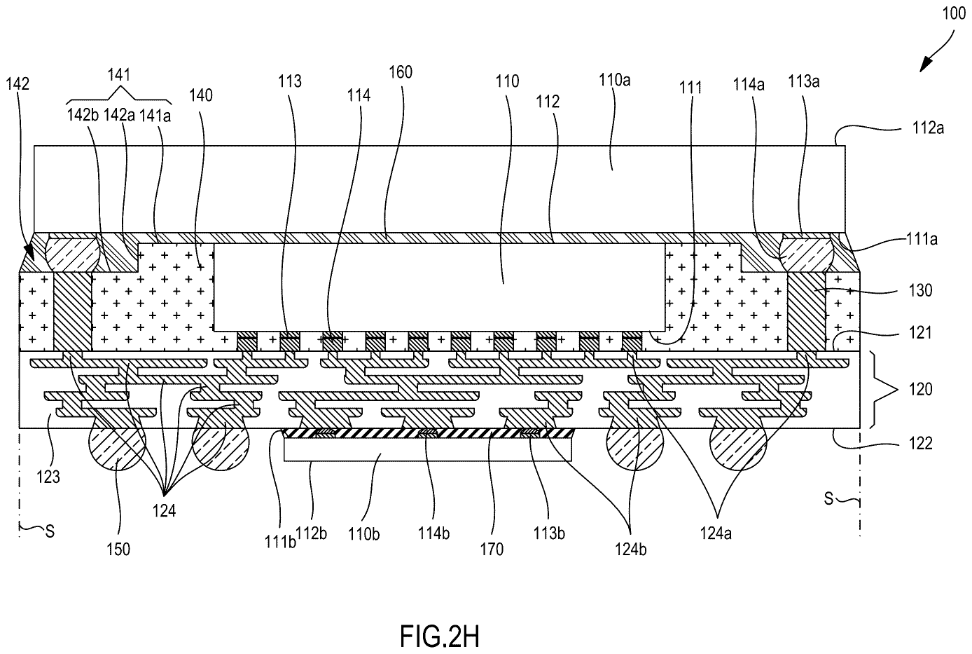

FIGS. 2A to 2H show cross-sectional views of an example method for manufacturing an example electronic device, such as electronic device 100 in FIG. 1. FIG. 2A shows a cross-sectional view of electronic device 100 at an early stage of manufacture. In the example shown in FIG. 2A, substrate 120 can be provided on the upper side of carrier 10. Carrier 10 can comprise or be referred to as a wafer, panel, support structure, plate, strip, or temporary carrier. Carrier 10 can comprise semiconductor material (e.g., Si), glass, ceramic, metal, or any other suitable material.

The width of carrier 10 can range from approximately 100 millimeters (mm) to approximately 300 mm. In some examples, carrier 10 can have a width of up to 600 mm. Carrier 10 can support the manufacture of multiple electronic devices 100 at once. Thus, while the present figures show one electronic device 100 (e.g., one substrate 120, one electronic component 110, one electronic component 110a, one electronic component 110b, etc.) being made over carrier 10, it is contemplated and understood that multiple identical, or nearly identical, semiconductor devices 100 are being simultaneously formed over carrier 110. In some examples, a temporary bonding layer can be interposed between carrier 10 and second side 122 of substrate 120. For example, the temporary bonding layer can be a heat release tape (or film) or an optical release tape (or film). In some examples, the adhesive strength of the temporary bonding layer can be weakened or removed by physical or chemical force. The temporary bonding layer can allow carrier 10 to be separated from substrate 120.

Substrate 120 can comprise dielectric structure 123 and conductive structure 124. In some examples, dielectric structure 123 can comprise or be referred to as one or more dielectric layers. For instance, the one or more dielectric layers can comprise one or more insulating layers, core layers, polymer layers, pre-preg layers, or solder mask layers stacked on each other. One or more layers or elements of conductive structure 124 can be interleaved with the layers of dielectric structure 123. In some examples, dielectric structure 123 can comprise FR4 (copper foil/glass fiber fabric/copper foil laminate), bismaleimide triazine (BT), polyimide (PI), benzocyclobutene (BCB), polybenzoxazole (PBO), Ajinomoto Build-up Film (ABF), resin, mold compound, ceramic, glass, or silicon. The thickness of individual layers of dielectric structure 123 can range from approximately 1 micrometer (μm) to approximately 1400 μm. A combined thickness of all layers of dielectric structure 123 can define the thickness of substrate 120. Dielectric structure 123 can maintain the shape of substrate 120 and can also structurally support conductive structure 124.

Conductive structure 124 can comprise or be referred to as one or more conductive layers defining signal distribution elements, such as, traces, vias, pads, conductive patterns, conductive paths, or under bump metals (UBMs). Conductive structure 124 can comprise copper, aluminum, gold, silver, nickel, palladium, alloy(s), or any other suitable electrically conductive material. The thickness of conductive structure 124 can range from approximately 1 μm to approximately 50 μm. The thickness of conductive structure 124 can refer to individual layers of conductive structure 124. Conductive structure 124 can provide electrical signal paths between electronic components.

Conductive structure 124 can comprise inward terminals 124a provided at first side 121 of substrate 120 and outward terminals 124b provided at second side 122 of substrate 120. In some examples, inward terminals 124a can comprise or be referred to as pads, lands, UBM, studs, microbumps, or pillars. In some examples, outward terminals 124b can comprise or be referred to as pads, lands, or UBM. Various conductive paths (e.g., traces and vias) of conductive structure 124 can couple inward terminals 124a to outward terminals 124b.

Substrate 120 can comprise a core or can be coreless. In some examples, substrate 120 can comprise or be referred to as a rigid printed circuit board, a flexible printed circuit board, a rigid laminate substrate, a flexible laminated substrate, a redistribution layer (RDL) substrate, a build-up substate, a ceramic substrate, a glass substrate, or a silicon substrate. In some examples, an area (or footprint) of substate 120 can varying according to the area or number of electronic components 110, 110a, or 110b mounted to substrate 120. In some examples, the thickness of substrate 120 can be between about 0.005 mm to about 4 mm.

In some examples, substrate 120 can be an RDL (or build-up) substrate. RDL substrates can comprise one or more conductive redistribution layers and one or more dielectric layers and (a) can be formed layer by layer over an electronic device to which the RDL substrate is coupled, or (b) can be formed layer by layer over a carrier (e.g., carrier 10) which can be removed (entirely or at least partially) after formation of the RDL substrate. For example, the RDL substate can be formed layer by layer over a carrier, an electronic device can then be connected to the RDL substrate, and the carrier can be removed with the electronic device connected to the RDL substrate. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, or (b) fan-in electrical traces within the footprint of the electronic device. The conductive patterns can be formed using a plating process, for example an electroplating process or an electroless plating process. The conductive patterns can comprise a conductive material, for example copper or other plateable metal. The locations of the conductive patterns can be made using a photo-patterning process, for example a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials, for example, PI, BCB, or PBO. Such dielectric materials can be spun-on or otherwise coated in liquid form rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples, the dielectric materials of the RDL substrates can comprise one or more inorganic dielectric layers. Some examples of one or more inorganic dielectric layers can comprise silicon nitride (Si3N4), silicon oxide (SiO2), or silicon oxynitride (SiON). The one or more inorganic dielectric layers can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure such as, for example, a dielectric material comprising BT or FR4 and these types of RDL substrates can comprise or be referred to as a coreless substrate. Substrate 120, as disclosed herein, can comprise an RDL substrate and can be formed on carrier 10.

In some examples, substrate 120 can be a pre-formed (or laminate) substrate. The pre-formed/laminate substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or ABF. The pre-formed substrate can include a permanent core structure comprising dielectric material such as, for example, BT or FR4, and dielectric and conductive layers can be provided over the permanent core structure. In other examples, the pre-formed substrate can be a coreless substrate that omits the permanent core structure. The pre-formed substrate can be referred to as a printed circuit board (PCB) or a laminate substrate. Such pre-formed substrate can be formed through a semi-additive or modified-semi-additive process.

FIG. 2B shows a cross-sectional view of electronic device 100 at a later stage of manufacture. In the example shown in FIG. 2B, vertical interconnects 130 are provided on first side 121 of substrate 120.

In accordance with various examples, vertical interconnects 130 can be provided in rows or columns over substrate 120. Vertical interconnects 130 are coupled to inward terminals 124a of conductive structure 124. Vertical interconnects 130 can comprise or be referred to as pillars, posts, pins, through mold vias (TMVs), ball-type structures such as copper core solder balls (CCBs), wires, or embedded interconnects (e.g., copper pillars surrounded by an encapsulant or other insulating material separate and distinct from encapsulant 140 in FIG. 2D). Vertical interconnects 130 can be provided by electrolytic plating, electroless plating, sputtering, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD), or a ball drop process. Vertical interconnects 130 can be made of copper, gold, silver, palladium, nickel, or any other suitable conductive material.

In some examples, vertical interconnects 130 can be formed directly on inward terminals 124a. For example, vertical interconnects 130 can be provided by plating or sputtering to fill openings in a patterned mask provided over first side 121 of substrate 120. The mask can be patterned to expose some of the inward terminals 124a. After vertical interconnects 130 are provided on the exposed inward terminals 124a, the mask can be removed. In some examples, vertical interconnects 130 can be pre-formed structures, which are subsequently bonded to inward terminals 124a. For example, vertical interconnects 130 can be metal (e.g., copper) pins and can be bonded to inward terminals 124a via solder or, in some examples, via solderless bonding. In some examples, the heights of vertical interconnects 130 can range from approximately 0.5 μm to approximately 800 μm.

FIG. 2C shows a cross-sectional view of electronic device 100 at a later stage of manufacture. In the example shown in FIG. 2C, electronic component 110 is provided on first side 121 of substrate 120.

Electronic component 110 can comprise first side 111 and second side 112 opposite to first side 111. In some examples, first side 111 can comprise or be referred to as an active side, and second side 112 of the electronic component can comprise or be referred to as an inactive side. Electronic component 110 can comprise a side wall connecting first side 111 and second side 112.

Electronic component 110 can comprise contacts 113 on first side 111. Contacts 113 can be provided in rows or columns on first side 111 of electronic component 110. Contacts 113 can comprise or be referred to as pads, terminals, posts, or interconnect structures. In some examples, contacts 113 can be bond pads exposed through a silicon oxide (SiO2) film, a silicon nitride (SiN) film, or passivation material on first side 111. In some examples, contacts 113 can be redistribution layer pads exposed by a dielectric material over first side 111. Contacts 113 can comprise an electrically conductive material such as aluminum, copper, an aluminum alloy, a copper alloy, or other metallic material.

Connectors 114 can couple contacts 113 of electronic component 110 to inward terminals 124a of substrate 120. In some examples, connectors 114 can comprise or be referred to as bumps, tin-lead (SnPb) bumps, leadfree bumps, pillars, copper pillars, solder capped metal pillars, stud bumps, posts, or interconnect structures. Connectors 114 can be provided on contact pads 113 of electronic component 110 by, for example, plating or a ball drop process. In some examples, connectors 114 can be surrounded by a passivation or other insulating material. Although electronic component 110 is shown with contacts 113 oriented toward substrate 120 and connectors 114 coupling electronic component 110 to inward terminals 124a in a flip-chip configuration, there can be examples where contact pads 113 are oriented away from substrate 120 and connectors 114 can be wires that couple electronic component 110 to inward terminals 124a in a wire-bond configuration.

In some examples, pick-and-place equipment can pick up electronic component 110 and place it on first side 121 of substrate 120. Connectors 114 can be located on inward terminals 124a of substrate 120. Subsequently, contacts 113 of electronic component 110 can be coupled to inward terminals 124a through connectors 114 by reflow, thermocompression bonding, laser assisted bonding, or any other suitable bonding process. In accordance with various examples, electronic component 110 can comprise or be referred to as a die, a chip, a package, an active device, or a passive device.

Electronic component 110 can be located in a center or central area of first side 121 of substrate 120, and vertical interconnects 130 can be located in an edge area and spaced apart from one, two, three, or four side wall(s) of electronic component 110. Prior to singulation of substrate 120, the edge area can be an area adjacent to the sawing lines for singulating individual electronic devices 100.

Electronic component 110 can be electrically coupled to vertical interconnects 130 through conductive structure 124 of substrate 120. In some examples, the height of electronic component 110 can be greater than the height of vertical interconnects 130. For example, the height of electronic component 110 can range from approximately 50 μm to approximately 850 μm. The area of electronic component 110 can range from approximately 0.5 mm by 0.5 mm to approximately 150 mm by 150 mm.

FIG. 2D shows a cross-sectional view of electronic device 100 at a later stage of manufacture. In the example shown in FIG. 2D, encapsulant 140 is provided over electronic component 110, first side 121 of substrate 120, and vertical interconnects 130.

In accordance with various examples, encapsulant 140 can be contact first side 121 of substrate 120, electronic component 110, and vertical interconnects 130. In some examples, encapsulant 140 can be a molded underfill (MUF) and can be interposed between first side 111 of the electronic component and first side 121 of substrate 120, and surround contacts 113 or connectors 114. In some examples, an underfill can be interposed between first side 111 of electronic component 110 and first side 121 of substrate 120, and encapsulant 140 can surround the underfill. For example, the underfill can be capillary underfill (CUF), non-conductive paste (NCP), non-conductive film (NCF), anisotropic conductive film (ACF), or anisotropic conductive paste (ACP). Encapsulant 140 can reduce occurrences of electronic component 110 from being separated from substrate 120 due to physical or chemical shock.

In some examples, encapsulant 140 can comprise or be referred to as a body or a molding. Encapsulant 140 can comprise an epoxy mold compound, a resin, an organic polymer with an inorganic filler, a curing agent, a catalyst, a coupling agent, a colorant, or a flame retardant, and can be provided by, for example, compression molding, transfer molding, liquid body molding, vacuum lamination, paste printing, film-assisted molding, or any other suitable deposition technique.

In accordance with various examples, upper side 141 of encapsulant 140 and second side 112 of electronic component can be coplanar. In some examples, encapsulant 140 can be provided covering second side 112 of electronic component 110. A top portion of encapsulant 140 can then be removed to expose second side 112 of electronic component 110. For example, the top portion of encapsulant 140 can be removed by a grinding or chemical etching process. The thickness or height of encapsulant 140 can be similar to the height of electronic component 110. The thickness of encapsulant 140 can range from approximately 20 μm to approximately 850 μm. Encapsulant 140 can protect electronic component 110, first side 121 of substrate 120, and vertical interconnects 130 from external elements.

FIG. 2E shows a cross-sectional view of electronic device 100 at a later stage of manufacture. In the example shown in FIG. 2E, cavity 142 is provided over vertical interconnects 130. In accordance with various examples, cavity 142 can be provided by removing a portion of encapsulant 140 from upper side 141. In response to forming cavity 142, the upper sides of vertical interconnects 130 can be exposed from encapsulant 140.

In some examples, encapsulant 140 can have a step that defines cavity 142 between the central area of encapsulant 140 and the lateral edge of encapsulant 140. Cavity 142 can be defined by vertical portion 142a of encapsulant 140 and lower horizontal portion 142b of encapsulant 140. Lower horizontal portion 142b can be closer to substrate 120 than upper horizontal portion 141a of first side 141. In this regard, upper horizontal portion 141a can protrude upward relative to lower horizontal portion 142b. The side wall of electronic component 110 can be covered with encapsulant 140. In some examples, the top side of vertical interconnect 130 can be exposed from the lower horizontal side 142b of encapsulant 140. In such examples, the top side of vertical interconnect 130 can be lower than upper horizontal side 141a of encapsulant 140.

In accordance with various examples, the upper sides of vertical interconnects 130 can be lower than second side 112 of electronic component 110. In some examples, a top portion of vertical interconnects 130 can be removed when forming cavity 142. Cavity 142 can be provided by using, for example, a diamond blade, a metal blade, a resin blade, or a laser beam. In some examples, the height of vertical interconnects 130 and the height of encapsulant 140, as measured at lower horizontal portion 142b, can range from approximately 50 μm to approximately 750 μm. In some examples, the difference between the height of vertical interconnects 130 and the height of second side 112 of electronic component 110, as measured from first side 121 of substrate 120 (e.g., the length of vertical portion 142a), can range from approximately 50 μm to approximately 300 μm, from approximately 50 μm to approximately 400 μm, or from approximately 50 μm to approximately 450 μm, although the scope of the disclosed subject matter is not limited in this respect.

FIG. 2F shows a cross-sectional view of electronic device 100 at a later stage of manufacture. In the example shown in FIG. 2F, electronic component 110a is provided over electronic component 110 and upper side 141 of encapsulant 140.

Electronic component 110a can comprise first side 111a and second side 112a opposite first 111a. Electronic component 110a can comprise contacts 113a on first side 111a. In some examples, first side 111a can comprise or be referred to as an active side of electronic component 110a. Connectors 114a can couple contacts 113a of electronic component 110a to vertical interconnects 130. In accordance with various examples, electronic component 110a can comprise or be referred to as a die, a chip, a package, an active device, or a passive device.

In accordance with various examples, electronic component 110a can cover electronic component 110 and vertical interconnects 130. For example, the area of electronic component 110a can be greater than the area of electronic component 110. In some examples, the area of electronic component 110a can range from approximately 1 mm by 1 mm to approximately 150 mm by 150 mm. In some examples, the thickness of electronic component 110a can range from approximately 50 μm to approximately 850 μm.

In accordance with various examples, connectors 114a can be accommodated in cavity 142 of encapsulant 140. Connectors 114a can protrude downward relative to first side 111a of electronic component 110a and can be coupled to or contact the upper sides of vertical interconnects 130. First side 111a of electronic component 110a can be spaced apart from second side 112 of electronic component 110 and upper horizontal portion 141a of encapsulant 140. For example, the sum of the height of contacts 113a and the height of connectors 114a can be greater than the difference between the height of electronic component 110 and the height of vertical interconnects 130. In some examples, the sum of the heights of contacts 113a and connectors 114a can range from approximately 50 μm to approximately 500 μm and the height of vertical portion 142a (i.e., the depth of cavity 142) can be between approximately 50 μm and approximately 300 μm. In some other examples, the height of vertical portion 142a can be between approximately 50 μm and approximately 400 μm. In some further examples, the height of vertical portion 142a can be between approximately 50 μm and approximately 450 μm. In general, the height of vertical portion 142a is less than the sum of the height of contacts 113a and connectors 114a.

In some examples, the bottom side of connector 114a is below upper horizontal portion 141a of first side 141 of encapsulant 140, and the top side of connector 114a is above upper horizontal portion 141a. In some examples, the height of connector 114a can be greater than the height of the vertical portion 142a of encapsulant 140. In some examples, second side 112 of electronic component 110 can be above lower horizontal portion 142b of first side 141 of encapsulant 140. Locating connectors 114a in cavity 142 can reduce the overall thickness of electronic device 100.

FIG. 2G shows a cross-sectional view of electronic device 100 at a later stage of manufacture. In the example shown in FIG. 2G, underfill 160 is provided between first side 111a of electronic component 110a and second side 112 of electronic component 110.

In accordance with various examples, underfill 160 can cover first side 141 of encapsulant 140 and second side 112 of electronic component 110. In some examples, underfill 160 can contact first side 111a of electronic component 110a, contact pads 113a, connectors 114a, second side 112 of electronic component 110, and first side 141 of encapsulant 140 (e.g., upper horizontal portion 141a, vertical portion 142a, and lower horizontal portion 142b). Underfill 160 can comprise or be referred to as a dielectric or insulating material, and, in some examples, can be free of inorganic fillers. In some examples, underfill 160 can be CUF, NCP, NCF, ACF, or ACP. In some examples, underfill 160 can be provided after electronic component 110a is coupled to contacts 113. In some examples, underfill 160 can be provided on second side 112 of electronic component 110 and first side 141 of encapsulant 140 prior to attaching electronic component 110a, and connectors 114a can be penetrate or be pressed through underfill 160. In some examples, underfill 160 can be provided on first side 111a of electronic component 110a prior to locating electronic component 110a over electronic component 110. In some examples, underfill 160 can be cured after being provided between electronic component 110a and electronic component 110 or after coupling connectors 114a to vertical interconnects 113. Underfill 160 can prevent electronic component 110a from separating from vertical interconnects 130 due to physical or chemical shock. Underfill 160 can insulate first side 111a of electronic component 110a from second side 112 of electronic component 110. In some examples, the thickness of underfill 160 interposed between first side 111a of electronic component 110a and second side 112 of electronic component 110 can range from approximately 50 μm to approximately 450 μm. In general, the maximum thickness of underfill 160 is less than the sum of the height of contacts 113a and connectors 114a. In some examples, a lateral side of the underfill 160 can be slanted, for example, at an acute angle with respect to the lower horizontal portion 142b of encapsulant 140.

FIG. 2H shows a cross-sectional view of electronic device 100 at a later stage of manufacture. In the example shown in FIG. 2H, carrier 10 is removed from second side 122 of substrate 120, and external interconnects 150 are provided on outward terminals 124b of substrate 120.

In accordance with various examples, heat, light, a chemical solution, or physical external force can be used separate carrier 10 from second side 122 of substrate 120. Removal of carrier 10 exposes outward terminals 124b on second side 122 of substrate 120.

In accordance with various examples, external interconnects 150 can be coupled to or contacting outward terminals 124b of conductive structure 124. External interconnects 150 can be electrically coupled to electronic component 110 through conductive structure 124 of substrate 120. External interconnects 150 can be electrically connected to electronic component 110a through conductive structure 124 of substrate 120 and vertical interconnects 130. In some examples, external interconnects 150 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 150 can be formed by providing a conductive material containing solder on outward terminals 124b by using a ball drop method and then performing a reflow process. External interconnects 150 can comprise or be referred to as conductive balls such as solder balls, conductive pillars such as copper pillars, or conductive posts each having a solder cap formed on a copper pillar. In some examples, the sizes of external interconnects 150 can range from approximately 25 μm to approximately 500 μm. In some examples, external interconnects 150 can be referred to as external input/output (I/O) terminals of electronic device 100. In some examples, electronic device 100 can be a land grid array (LGA) and outward terminals 124b can serve as external input/output (I/O) terminals of electronic device 100.

In some examples, electronic component 110b can be provided on second side 122 of substrate 120. Electronic component 110b can be coupled to outward terminals 124b of substrate 120. Electronic component 110b can comprise or be referred to as a die, a chip, a package, an active device, or a passive device. In some examples, electronic component 110b can be electrically coupled to electronic component 110 or external interconnects 150 through conductive structure 124. In some examples, electronic component 110b can be electrically coupled to electronic component 110a through conductive structure 124 and vertical interconnects 130.

Electronic component 110b can comprise first side 111b and second side 112b. In some examples, first side 111b can comprise or be referred to as an active side of electronic component 110b. Electronic component 110b can comprise contacts 113b on first side 111b. Connectors 114b can electrically couple contacts 113b of electronic component 110b to outward terminals 124b. In some examples, underfill 170 can be provided between first side 111a of electronic component 110b and second side 122 of substrate 120. In some examples, the elements, features, materials, or manufacturing methods similar of underfill 170 can be similar or the same as those of underfill 160. In some examples, an encapsulant can be provided over electronic component 110b and second side 122 of substrate 120. In some examples, the thickness of electronic component 110b can be smaller than the thickness of external interconnects 150. For example, the thickness of electronic component 110b can range from approximately 25 μm to approximately 200 μm.

After providing external interconnects 150, a singulation process can be performed to separate individual electronic devices 100. Singulation can be performed by sawing along saw lines S. During the singulation process, a sawing tool (e.g., diamond blade wheel or laser beam) can cut through substrate 120 and encapsulant 140 to separate individual electronic devices 100. After singulation, lateral sides of substrate 120 and encapsulant 140 can be coplanar. In some examples, a lateral side of encapsulant 140 can extend beyond lateral side(s) of the top electronic component 110a.

Electronic device 100 can comprise electronic components 110, 110a, and 110b, substrate 120, vertical interconnects 130, encapsulant 140, external interconnects 150, and underfill materials 160 and 170. Electronic device 100 can reduce the heights of vertical interconnects 130 by exposing the upper sides of vertical interconnects 130 at lower horizontal portion 142b of encapsulant 140. In electronic device 100, connectors 114a of electronic component 110a can be accommodated in cavity 142 of encapsulant 140, and an overall thickness of electronic device 100 can be reduced.

In some examples, by providing cavity 142 in encapsulant 140, connector 114a can be positioned lower than the upper horizontal portion 141a of encapsulant 140, and connector 114a can couple to vertical interconnect 130 at lower horizontal portion 142b (e.g., at a point lower than the upper horizontal portion 141a and second side 112 of electronic component 110). This arrangement allows the space between the upper horizontal portion 141a of encapsulant 140 and the first side 111a of second electronic component 110a to be reduced by the height of the vertical portion 142b of encapsulant 140. As a result, the overall thickness of the electronic device 100 can be reduced by the height of the vertical portion 142b. Similarly, providing cavity 142 in encapsulant 140 can allow for the thickness of first electronic component 110 to be increased by the height of the vertical portion 142b without increasing the overall thickness of electronic device 100, or a combination of a reduced thickness of electronic device 100 and an increased thickness of first electronic component 110 can be achieved.

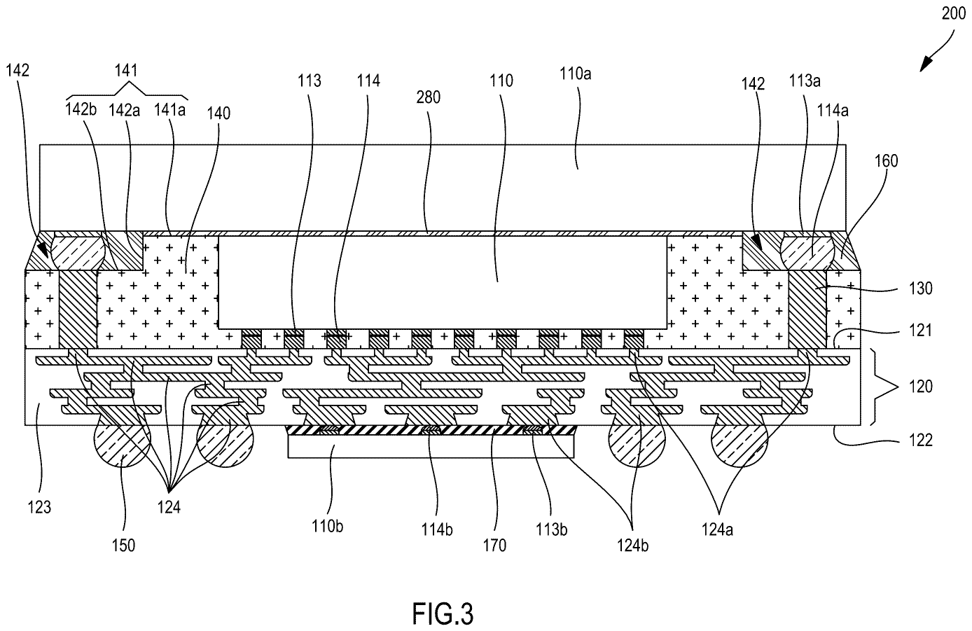

FIG. 3 shows a cross-sectional view of an example of electronic device 200. In the example shown in FIG. 3, electronic device 200 can comprise electronic components 110, 110a, and 110b, substrate 120, vertical interconnects 130, encapsulant 140, external interconnects 150, underfill material 160, and underfill material 170, similar to electronic device 100 in FIG. 1. In accordance with various examples, electronic device 200 can further include adhesive 280 between electronic component 110 and electronic component 110a.

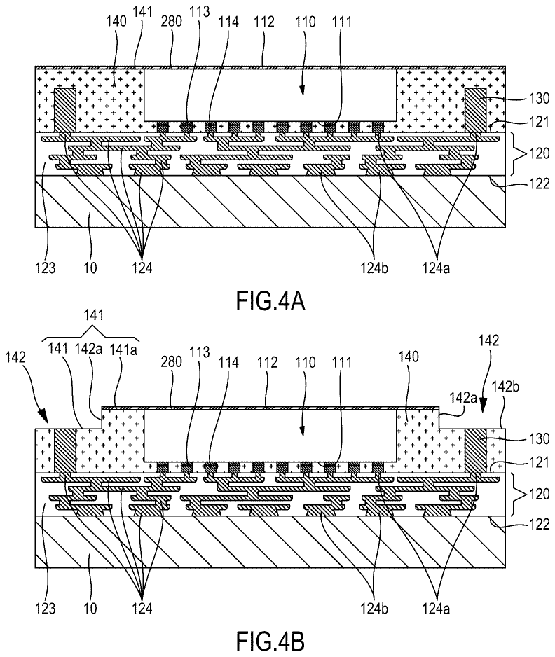

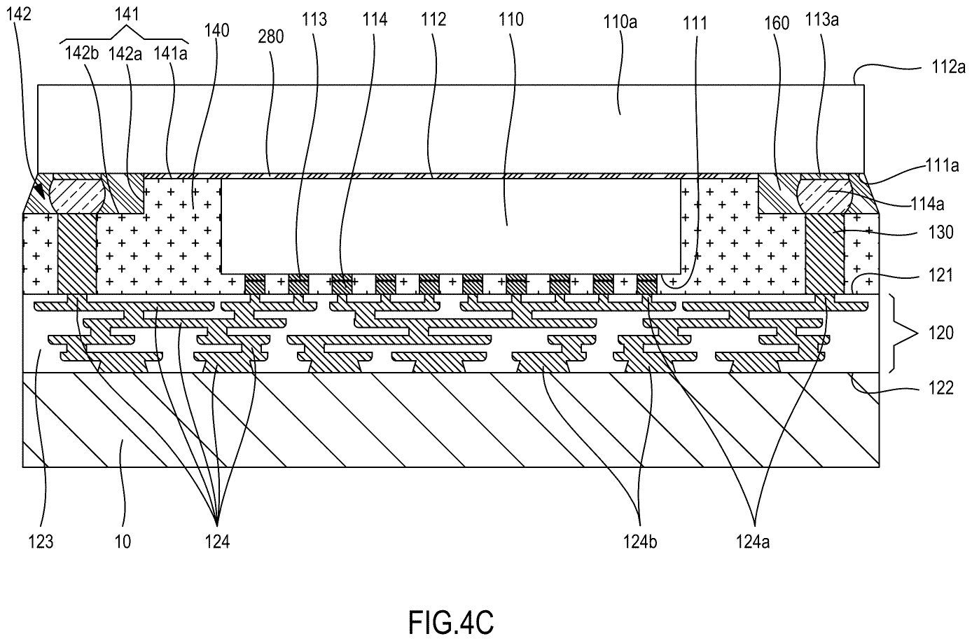

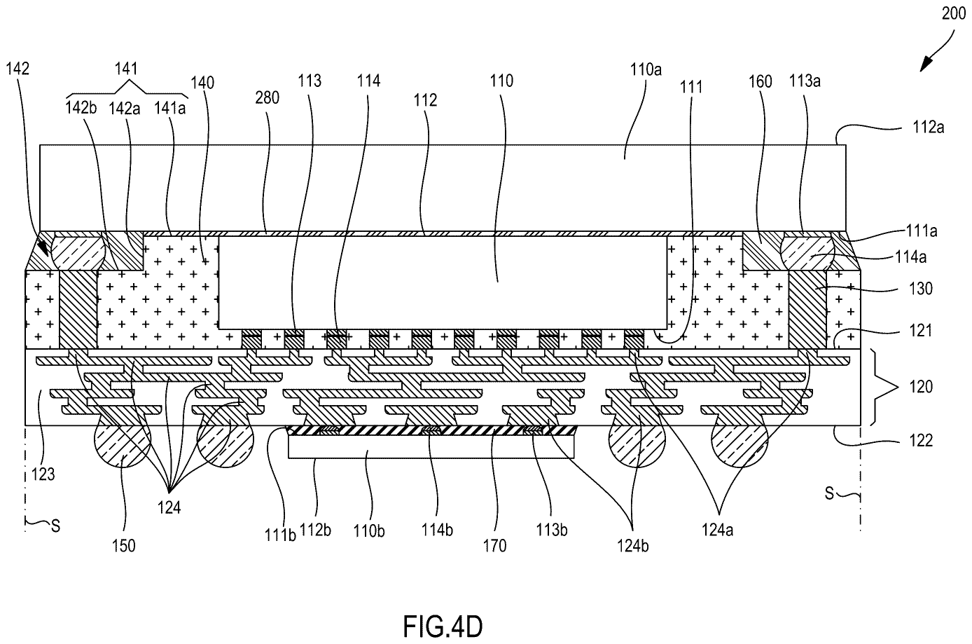

FIGS. 4A to 4D show cross-sectional views of an example method for manufacturing an example electronic device, such as electronic device 200 in FIG. 3. FIG. 4A shows a cross-sectional view of electronic device 200 at a later stage of manufacture. For example, electronic device 200 of FIG. 4A can be manufactured as shown in in FIGS. 2A to 2D. Adhesive 280 can then be provided to over first side 141 of encapsulant 140 and second side 112 of electronic component 110. In some examples, adhesive 280 can cover first side 141 of encapsulant 140 and second side 112 of electronic component 110. Adhesive 280 can be in contact with upper side 141 of encapsulant 140 and second side 112 of electronic component 110.

In some examples, adhesive 280 can include an adhesive comprising a low-κ material (i.e., having a dielectric constant (κ) that is lower than the dielectric constant of silicon dioxide), an underfill material, or an inorganic passivation. For example, adhesive 280 can comprise or be referred to as a polymer or an insulating material. Adhesive 280 can be provided by spin coating, doctor blade coating, casting, painting, spray coating, slot die coating, curtain coating, slide coating, knife over edge coating, screen printing, pad printing, gravure printing, flexography printing, offset printing, an inkjet printing, direct attachment of a bonding film or a bonding tape, or any other suitable deposition technique. For example, adhesive 280 can comprise a silicon dioxide (SiO2) or silicon nitride (SiN) deposition. In some examples, the thickness of adhesive 280 can range from approximately 0.1 μm to approximately 100 μm.

FIG. 4B shows a cross-sectional view of electronic device 200 at a later stage of manufacture. In the example shown in FIG. 4B, cavity 142 can be provided in encapsulant 140. In some examples, cavity 142 can be provided by removing an edge (or perimeter) area of adhesive 280 and a top portion of the edge area of encapsulant 140. Cavity 142 can expose the upper sides of vertical interconnects 130. Cavity 142 can have elements, features, materials, or manufacturing methods similar to those of cavity 142 in electronic device 100 shown in FIG. 2E. For example, cavity 142 can be defined by lower horizontal portion 142b and vertical portion 142a of first side 141, and encapsulant 140 can have a step between a central area (e.g., upper horizontal portion 141a) and a peripheral area of upper side 141 of encapsulant 140. In response to formation of cavity 142, adhesive 280 can be located on upper horizontal portion 141a of encapsulant 140 and cavity 142 (e.g., lower horizontal portion 142b and vertical portion 142a of encapsulant 140) can be devoid of or exposed from adhesive 280.

FIG. 4C shows a cross-sectional view of electronic device 200 at a later stage of manufacture. In the example shown in FIG. 4C, electronic component 110a is provided over adhesive 280 and cavity 142. Electronic component 110a can have corresponding elements, features, materials, or manufacturing methods to those of electronic component 110a of electronic device 100 shown in FIG. 2F.

In accordance with various examples, connectors 114a can be accommodated in cavity 142. Connectors 114a can be coupled to vertical interconnects 130. Underfill 160 can be disposed in cavity 142. Underfill 160 can be disposed around connectors 114a and over lower horizontal portion 142b of encapsulant 140. Underfill 160 can cover or contact vertical portion 142a of encapsulant 140 and the lateral sides of adhesive 140. Elements, features, materials, or manufacturing methods of underfill 160 can be similar to or the same as those of encapsulant 160 of electronic device 100, as described above with reference to FIG. 2G.

A central area of first side 111a of electronic component 110a can be in contact with adhesive 280. In some examples, after locating electronic component 110a on adhesive 280 and vertical interconnects 130, adhesive 280 can be cured, thereby coupling first side 111a of electronic component 110a to second side 112 of electronic component 110. Coupling electronic component 110a to electronic component 110 via adhesive 280 can increase the bonding strength between electronic component 110 and electronic component 110a. In this regard, using adhesive 280, in addition to underfill 160, can reduce occurrences of separation of electronic component 110a from electronic component 110 or from vertical interconnects 130.

FIG. 4D shows a cross-sectional view of electronic device 200 at a later stage of manufacture. In the example shown in FIG. 4D, carrier 10 is removed from second side 122 of substrate 120, and external interconnects 150 are provided on second side 122 of substrate 120. In some examples, electronic component 110b and underfill 170 can be provided on second side 122 of substrate 120. External interconnects 150, electronic component 110b, and underfill 170 can have elements, features, materials, or manufacturing methods similar to of the same as those of external interconnects 150, electronic component 110b, and underfill 170, respectively, of electronic device 100 shown in FIG. 2H.

After providing external interconnects 150, a singulation process can be performed to separate individual electronic devices 200. Singulation can be performed by sawing along saw lines S. During the singulation process, a sawing tool (e.g., diamond blade wheel or laser beam) can cut through substrate 120 and encapsulant 140 to separate individual electronic devices 200. After singulation, lateral sides of substrate 120 and encapsulant 140 can be coplanar. In some examples, a lateral side of encapsulant 140 can extend beyond a lateral sides of the top electronic component 110a.

Electronic device 200 can comprise electronic components 110, 110a, and 110b, substrate 120, vertical interconnects 130, encapsulant 140, external interconnects 150, underfill material 160, underfill material 170, and adhesive 280. Electronic device 200 can reduce the heights of vertical interconnects 130 through cavity 142 of encapsulant 140. In electronic device 200, connectors 114a can be accommodated in cavity 142 of encapsulant 140, and thus the overall thickness of electronic device 200 can be reduced. In electronic device 200, first side 111a of electronic component 110a and second side 112 of electronic component 110 can be electrically insulated from each other by adhesive 280 having a relatively small thickness, and the bonding force can be increased. In other examples, cavity 142 allows the height of electronic component 110 to be increased without increasing the overall height of electronic device 200.

In some examples, by providing cavity 142 in encapsulant 140, connector 114a can be positioned lower than upper horizontal portion 141a of encapsulant 140, and connector 114a can couple to vertical interconnect 130 at lower horizontal portion 142b, which can be lower than upper horizontal portion 141a of encapsulant 140 and second side 112 of electronic device 110. This arrangement allows the space between the upper horizontal portion 141a of encapsulant 140 and first side 111a of second electronic component 110a to be reduced by the depth of cavity 142 (i.e., by height of the vertical portion 142b). As a result, the overall thickness of the electronic device 200 can be reduced by the height of the vertical portion 142b. Alternatively, providing cavity 142 in encapsulant 140 can allow for an increased thickness of first electronic component 110 by the height of the vertical side 142b without increasing the overall thickness of electronic device 200, or a combination of a reduced thickness of electronic device 200 and an increased thickness of first electronic component 110 can be achieved.

The present disclosure includes reference to certain examples. It will be understood by those skilled in the art, however, that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

1. An electronic device, comprising:
a substrate comprising a first side, a second side opposite to the first side, a dielectric structure, and a conductive structure;
a first electronic component over the first side of the substrate and coupled to the conductive structure;
an encapsulant over the first side of the substrate and covering a lateral side of the first electronic component, wherein the encapsulant has a first side facing away from the substrate, and a cavity in the first side of the encapsulant;
a second electronic component over the first electronic component and over the encapsulant;
a vertical interconnect in the encapsulant and coupled to the conductive structure; and
a connector coupled to the vertical interconnect and the second electronic component, wherein the connector is in the cavity.

2. The electronic device of claim 1, comprising:
an underfill in the cavity and covering a lateral side of the connector.

3. The electronic device of claim 2, wherein the underfill is between the first electronic component and the second electronic component.

4. The electronic device of claim 2, comprising an adhesive between the first electronic component and the second electronic component, wherein the underfill covers a lateral side of the adhesive.

5. The electronic device of claim 1, wherein a lateral side of the encapsulant is coplanar with a lateral side of the substrate.

6. The electronic device of claim 1, wherein a lateral side of the encapsulant extends beyond a lateral side of the second electronic component.

7. The electronic device of claim 1, wherein a height of the connector is greater than a depth of the cavity.

8. The electronic device of claim 1, wherein the first side of the encapsulant comprises an upper horizontal portion, a lower horizontal portion, and a vertical portion extending between the upper horizontal portion and the lower horizontal portion, wherein the lower horizontal portion and the vertical portion define the cavity, and wherein a thickness of the encapsulant, as measured at the upper horizontal portion, is greater than a thickness of the encapsulant, as measured at the lower horizontal portion.

9. The electronic device of claim 1, comprising a third electronic component coupled to the second side of the substrate and coupled to the conductive structure.

10. The electronic device of claim 1, wherein the first side of the encapsulant comprises an upper horizontal portion, and an upper side of the vertical interconnect is lower than the upper horizontal portion.

11. An electronic device, comprising:
a substrate having a first side, a second side opposite to the first side, a dielectric structure, and a conductive structure;
a first electronic component coupled to the first side of the substrate and coupled to the conductive structure, wherein the first electronic component has an active side facing the first side of the substrate, and a backside facing away from the first side of the substrate;
an encapsulant coupled to the first side of the substrate and over a lateral side of the substrate, wherein the encapsulant comprises a central portion, and a step located between the central portion and a lateral side of the encapsulant, wherein the step comprises a vertical portion of the encapsulant and a lower horizontal portion of the encapsulant;
a connector over the lower horizontal portion of the encapsulant and coupled to the conductive structure; and
a second electronic component coupled to the connector and having a first side facing the encapsulant and a second side facing away from the encapsulant;
wherein the central portion of the encapsulant comprises an upper horizontal portion, and the lower horizontal portion of the step is lower than the upper horizontal portion.

12. The electronic device of claim 10, comprising a vertical interconnect in the encapsulant, wherein the vertical interconnect is coupled between the connector and the conductive structure.

13. The electronic device of claim 10, comprising an underfill covering the vertical portion of the encapsulant, the lower horizontal portion of the encapsulant, and a lateral side of the connector.

14. The electronic device of claim 10, comprising an adhesive between the upper horizontal portion of the encapsulant and the first side of the second electronic component.

15. The electronic device of claim 14, wherein the adhesive is between the first electronic component and the second electronic component.

16. The electronic device of claim 10, wherein a bottom side of the connector is below the upper horizontal portion of the encapsulant.

17. A method to manufacture an electronic device, comprising:
providing a substrate comprising a first side, a second side opposite to the first side, a dielectric structure, and a conductive structure;
providing a vertical interconnect over the first side of the substrate and coupled to the conductive structure;
providing a first electronic component over the first side of the substrate and coupled to the conductive structure;
providing an encapsulant over the first side of the substrate and covering a lateral side of the first electronic component and a lateral side of the vertical interconnect, wherein the encapsulant has a first side facing away from the substrate;
providing a cavity in the first side of the encapsulant at a lateral side of the encapsulant;
providing a connector coupled to the vertical interconnect, wherein the connector is in the cavity; and
providing a second electronic component over the first electronic component and over the encapsulant, wherein the second electronic component is coupled to the connector.

18. The method of claim 17, comprising providing an underfill in the cavity and covering a lateral side of the connector.

19. The method of claim 18, wherein the underfill is between the first side of the encapsulant and a first side of the second electronic component.

20. The method of claim 18, comprising providing an adhesive between a first side of the encapsulant and a first side of the second electronic component, wherein the underfill covers a lateral side of the adhesive.
